(19) United States
(12) Patent Application Publication
(10) Pub. No.: US 2014/0174516 A1
(43) Pub. Date: Jun. 26, 2014

(54) SOLAR CELL AND MANUFACTURING METHOD THEREOF

(71) Applicant: Samsung Electronics Co., Ltd., Suwon-Si (KR)

(72) Inventors: Young Moon CHOI, Seoul (KR); Dong Kyun KIM, Yongin-si (KR); Yun Gi KIM, Yongin-si (KR); Eun Cheol DO, Yongin-si (KR); Yeon Il LEE, Seongnam-si (KR)

(21) Appl. No.: 13/921,546

(22) Filed: Jun. 19, 2013

(30) Foreign Application Priority Data
Dec. 21, 2012 (KR) 10-2012-0151134

(51) Int. Cl. H01L 31/0687; H01L 31/18

(52) U.S. Cl. CPC H01L 31/0687; H01L 31/18
USPC 136/255; 438/98

(57) ABSTRACT

A solar cell includes a crystalline photovoltaic layer, a first impurity region having a first conductivity type and a second impurity region having a second conductivity type in the photovoltaic layer, a third impurity region having the first conductivity type in the first impurity region, a fourth impurity region having the second conductivity type in the second impurity region, a first barrier layer and a second barrier layer contacting the third impurity region and the fourth impurity region, respectively, and a first electrode and a second electrode contacting the first barrier layer and the second barrier layer, respectively. The first impurity region and the second impurity region are spaced apart from each other. The third impurity region and the fourth impurity region have an impurity concentration higher than the first impurity region the second impurity region, respectively.

### CROSS REFERENCE TO RELATED APPLICATION

This application claims priority under 35 U.S.C. §119 to Korean Patent Application No. 10-2012-0151134 filed in the Korean Intellectual Property Office on Dec. 21, 2012, the entire contents of which are incorporated herein by reference.

### BACKGROUND

(a) Field

Some example embodiments relate to a solar cell and a manufacturing method thereof.

(b) Description of the Related Art

Fossil fuels, such as coal and petroleum, are used as energy sources. However, fossil fuels are being exhausted and cause global warming and environmental pollution. Solar light, tidal power, wind power, geothermal heat and the like are being studied as alternative energy sources for replacing fossil fuels.

Among them, a technology that is capable of converting solar light into electricity takes the lead. Various materials and devices are being developed for solar cells that convert solar light into electricity, in particular, solar cells using crystalline materials such as silicon. However, conventional solar cell technologies may have insufficient power generation efficiency due to electron-hole recombination, etc.

### SUMMARY

According to an example embodiment, a solar cell includes a photovoltaic layer including a crystalline photovoltaic material, a first impurity region having a first conductivity type in the photovoltaic layer, a second impurity region having a second conductivity type in the photovoltaic layer, the second impurity region spaced apart from the first impurity region, a third impurity region having the first conductivity type in the first impurity region, the third impurity region having an impurity concentration higher than the first impurity region, a fourth impurity region having the second conductivity type in the second impurity region, the fourth impurity region having an impurity concentration higher than the second impurity region, a first barrier layer contacting the third impurity region, a second barrier layer contacting the fourth impurity region, a first electrode contacting the first barrier layer, and a second electrode contacting the second barrier layer.

An impurity included in the third impurity region may be heavier than an impurity included in the first impurity region, an impurity included in the fourth impurity region may be heavier than an impurity included in the second impurity region, the third impurity region may be shallower than the first impurity region, and the fourth impurity region may be shallower than the second impurity region.

Each of the first barrier layer and the second barrier layer may include a metal silicide.

The first impurity region, the second impurity region, the third impurity region and the fourth impurity region may abut onto a first surface of the photovoltaic layer. The solar cell may further include a back surface field layer on a second surface of the photovoltaic layer, the second surface opposite the first surface.

The first impurity region and the second impurity region may abut onto opposite surfaces of the photovoltaic layer. At least one of the first electrode and the second electrode may have an inclined lateral surface.

According to an example embodiment, a method of manufacturing a solar cell includes forming a first impurity region including a first impurity having a first conductivity type in a photovoltaic layer including a crystalline photovoltaic material, forming a second impurity region including a second impurity having a second conductivity type in the photovoltaic layer, the second impurity region spaced apart from the first impurity region, introducing a third impurity having the first conductivity type in the first impurity region, the third impurity having an impurity concentration higher than an impurity concentration of the first impurity region, introducing a fourth impurity having the second conductivity type in the second impurity region, the fourth impurity having an impurity concentration higher than an impurity concentration of the second impurity region, forming a first electrode on a first portion of the photovoltaic layer, the first portion including the third impurity, forming a second electrode on a second portion of the photovoltaic layer, the second portion including the fourth impurity, and heat treating the photovoltaic layer to activate the third impurity and the fourth impurity to form a third impurity region and a fourth impurity region.

The first impurity region and the second impurity region may be formed by introducing the first impurity in the photovoltaic layer at a depth greater than a depth of the third impurity introduced in the first impurity region, introducing the second impurity in the photovoltaic layer at a depth greater than a depth of the fourth impurity introduced in the second impurity region, and heat treating the photovoltaic layer to activate the first impurity and the second impurity. The first impurity may be lighter than the third impurity, and the second impurity may be lighter than the fourth impurity.

Heat treating the photovoltaic layer to activate the third impurity and the fourth impurity may be performed at a temperature lower than a temperature for heat treating the photovoltaic layer to activate the first impurity and the second impurity and for a duration shorter than a duration for heat treating the photovoltaic layer to activate the first impurity and the second impurity.

Heat treating the photovoltaic layer to activate the third impurity and the fourth impurity may include forming metal silicide layers between the first electrode and the third impurity region and between the second electrode and the fourth impurity region.

### BRIEF DESCRIPTION OF THE DRAWINGS

These and/or other aspects will become apparent and more readily appreciated from the following description of the embodiments, taken in conjunction with the accompanying drawings of which:

FIG. 1 and FIG. 2 are schematic sectional views of a solar cell according to an example embodiment.

FIG. 3 to FIG. 8 are schematic sectional views sequentially illustrating a method of manufacturing a solar cell according to an example embodiment.

FIG. 9 is a schematic sectional view of a solar cell according to an example embodiment.

### DETAILED DESCRIPTION OF EXAMPLE EMBODIMENTS

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted. In the drawing, parts having no relationship with the explanation are omitted for clarity.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

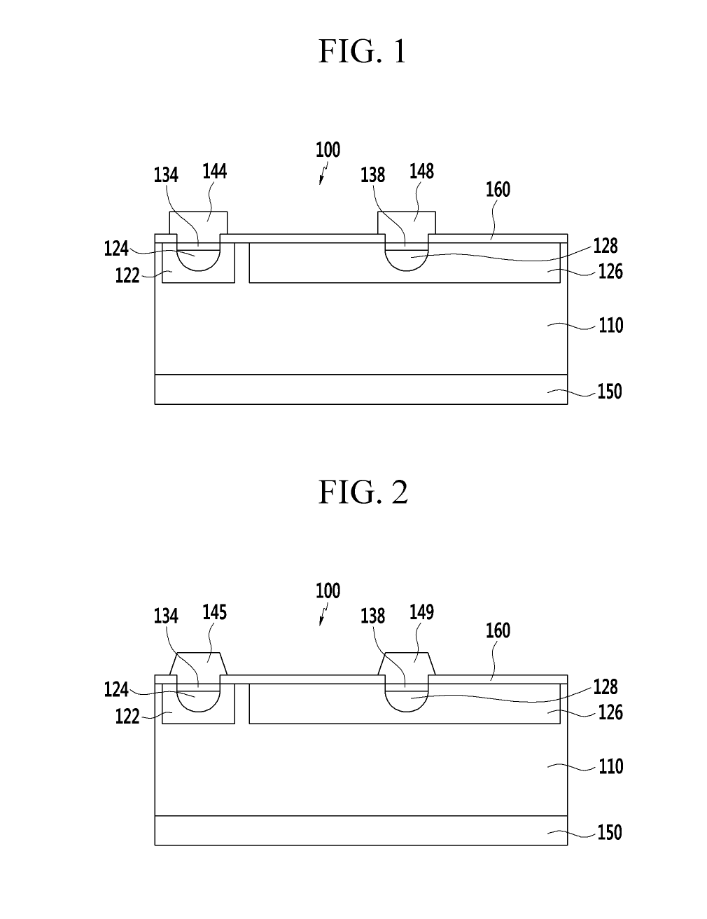

A solar cell according to an example embodiment is described in detail with reference to FIG. 1 and FIG. 2. FIG. 1 and FIG. 2 are schematic sectional views of a solar cell according to an example embodiment.

Referring to FIG. 1 and FIG. 2, a solar cell 100 according to an example embodiment may include a photovoltaic layer 110, a base electrode 144 or 145, an emitter electrode 148 or 149, an insulating layer 160, and a back surface field (BSF) layer 150. The base electrode 144 or 145, the emitter electrode 148 or 149, and the insulating layer 160 may be disposed on the photovoltaic layer 110, and the BSF layer 150 may be disposed under the photovoltaic layer 110.

The photovoltaic layer 110 may generate electric current upon receipt of light, and may include a crystalline photovoltaic material such as silicon. The photovoltaic layer 110 may include an N-type or P-type substrate. Hereinafter, one of N-type and P-type is referred to as a first conductivity type, and the other is referred to a second conductivity type. The photovoltaic layer 110 may have the first conductive type.

The photovoltaic layer 110 may include a pair of low concentration impurity regions 122 and 126 therein, and may further include a pair of high concentration impurity regions 124 and 128 in the respective low concentration impurity regions 122 and 126. The impurity regions 122, 124, 126 and 128 may abut onto a top surface of the photovoltaic layer 110.

The pair of the low concentration impurity regions 122 and 126 may include a low concentration base region 122 having the first conductivity type like the photovoltaic layer 110 and a low concentration emitter region 126 having the second conductivity type. The low concentration base region 122 and the low concentration emitter region 126 may be spaced apart from each other, and the low concentration emitter region 126 may be larger than the low concentration base region 122. The high concentration impurity regions 124 and 128 may include a high concentration base region 124 of the first conductivity type and a high concentration emitter region 128 of the second conductivity type. The high concentration base region 124 may be disposed in the low concentration base region 122, and may have impurity concentration higher than the low concentration base region 122.

The high concentration emitter region 128 may be disposed in the low concentration emitter region 126, and may have impurity concentration higher than the low concentration emitter region 126. The high concentration impurity regions 124 and 128 may be shallower than the low concentration impurity regions 122 and 126 such that a distance from the top surface of the photovoltaic layer 110 to a lower boundary of the high concentration impurity regions 124 and 128 may be shorter than a distance from the top surface of the photovoltaic layer 110 to a lower boundary of the low concentration impurity regions 122 and 126. The impurity contained in the high concentration impurity regions 124 and 128 may be heavier than the impurity contained in the low concentration impurity regions 122 and 126.

First and second barrier layers 134 and 138 may be disposed on the high concentration impurity regions 124 and 128. The first and second barrier layers 134 and 138 may include an alloy of a metal contained in the electrodes 144, 145, 148 and 149 and a photovoltaic material contained in the photovoltaic layer 110, for example, a metal silicide.

The insulating layer 160 may be disposed on the photovoltaic layer 110, and may have contact holes exposing the first and second barrier layers 134 and 138. The insulating layer 160 may be a single oxide layer or may have a dual-layered structure including an oxide layer and an anti-reflection layer.

The base electrode 144 or 145 and the emitter electrode 148 or 149 may be disposed on the insulating layer 160, and may be in contact with the first and second barrier layers 134 and 138 through the contact holes (not shown). Referring to FIG. 2, lateral surfaces of the base electrode 145 and the emitter electrode 149 may be inclined, which may reduce reflection of light by the electrodes 145 and 149. The base electrode 144 or 145 and the emitter electrode 148 or 149 may include a silicidable metal, for example, Ti, Co, Ni.

The BSF layer 150 may be omitted. Solar light may be incident from a top or a bottom of the solar cell 100.

In the above-described solar cell 100, the difference in the concentration between the photovoltaic layer 110 and the low concentration base region 122 and between the low concentration base region 122 and the high concentration base region 124 may cause an electric field that may suppress minority carriers generated in the photovoltaic layer 110 by light from flowing toward base. As a result, the minority carriers may be suppressed from re-combining with minority carriers near a surface of the base electrode 144 or 145. Therefore, a possibility of electron-hole re-combination in the solar cell 100 may be decreased compared with a structure consisting of the low concentration base region 122 or a structure consisting of the high concentration base region 124. Similarly, minority carriers may be suppressed from flowing into a surface of the emitter electrode 148 or 149, and thus a possibility of electron-hole re-combination near the emitter electrode 148 or 149 may also be reduced.

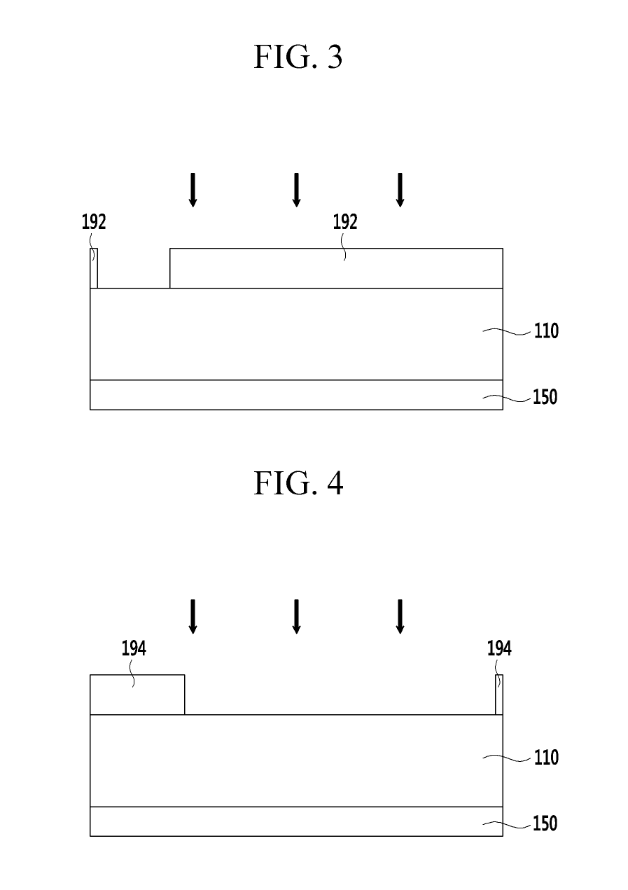

A method of manufacturing a solar cell according to an example embodiment is described in detail with reference to FIG. 3 to FIG. 8. FIG. 3 to FIG. 8 are schematic sectional views sequentially illustrating a method of manufacturing a solar cell according to an example embodiment.

Referring to FIG. 3, a first photoresist layer 192 may be formed on a top surface of a photovoltaic layer 110 of a first conductivity type having a bottom surface on which a BSF layer 150 is disposed. Thereafter, impurity of the first conductivity type may be implanted into the photovoltaic layer 110, for example, with ion implantation energy of about 5 keV and impurity concentration equal to or less than about 1×10¹⁵ atm/cm³.

According to an example embodiment, ion doping instead of ion implantation may be used. For example, a surface of the photovoltaic layer 110 may be exposed to a liquid of POCl₃ (phosphoryl chloride) or a gas of BBr₄ such that phosphorous (P) or boron (B) may be doped into the photovoltaic layer 110.

Referring to FIG. 4, the first photoresist layer 192 may be removed, and a second photoresist layer 194 may be formed. Thereafter, impurity of the second conductivity type may be implanted into the photovoltaic layer 110, for example, with ion implantation energy of about 5 keV and impurity concentration less than about 1×10¹⁵ atm/cm³. Similarly, ion doping may be also used instead of ion implantation at this stage.

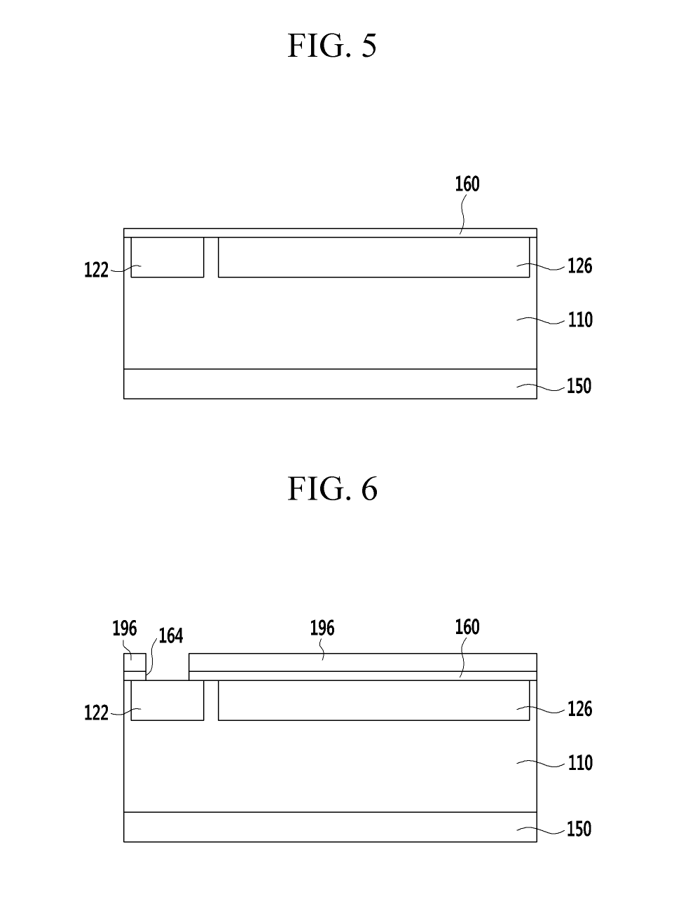

The order of the process shown in FIG. 3 and the process shown in FIG. 4 may be exchanged. Referring to FIG. 5, the photovoltaic layer 110 may be subjected to a first heat treatment such that the impurities introduced as shown in FIG. 3 and FIG. 4 may be activated to form a low concentration base region 122 and a low concentration emitter region 126. According to an example embodiment, the heat treatment may be performed under exposure to oxygen to form an insulating layer 160 including an oxide on the surface of the photovoltaic layer 110. The temperature for the heat treatment may be equal to higher than about 900° C. According to an example embodiment, the insulating layer 160 may be formed by chemical vapor deposition, etc., and may include a nitride.

Referring to FIG. 6, a third photoresist layer 196 may be formed on the insulating layer 160, and the insulating layer 160 may be patterned to form a first contact hole 164 exposing the low concentration base region 122.

Subsequently, an impurity of the first conductivity type may be ion implanted. The ion implantation energy and the impurity concentration in this process may be higher than the ion implantation energy and the impurity concentration for the low concentration base region 122, respectively. For example, the ion implantation energy may be from about 20 keV to about 50 keV, and the impurity concentration may be equal to or higher than about 1×10¹⁵ atm/cm³.

The impurity implanted in this process may be heavier than the impurity contained in the low concentration base region 122, and may include As and BF₂, for example. The implantation depth of the impurity in this process may be less than the implantation depth of the impurity for the low concentration base region 122. The implantation of a heavy impurity with high concentration and high energy may cause pre-amorphization of corresponding portions of the photovoltaic layer 110.

According to an example embodiment, doping of liquid or gaseous ions or partial doping using laser beams may be used instead of the ion implantation.

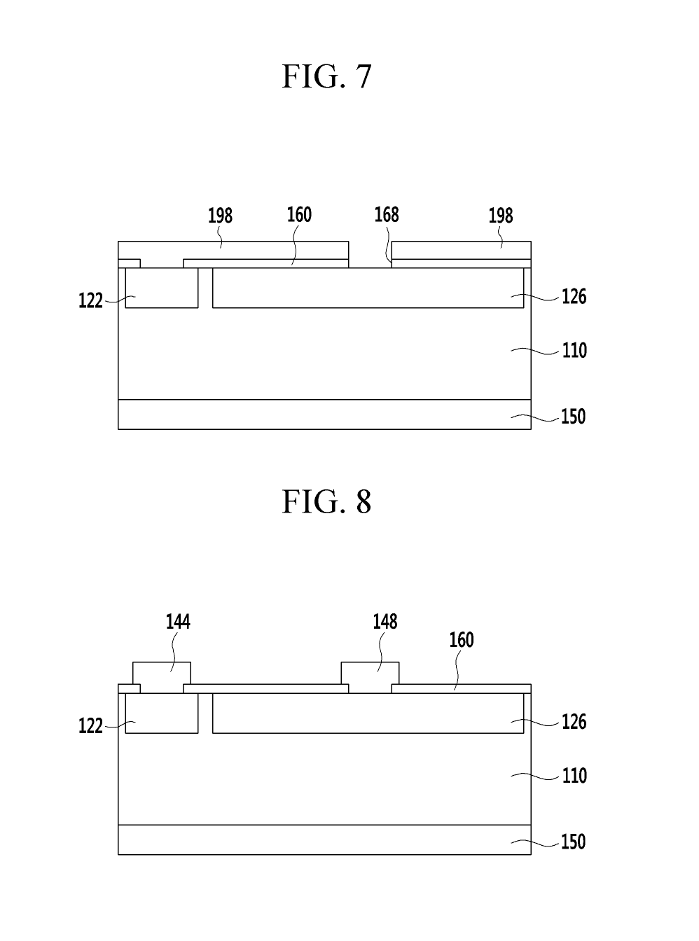

Referring to FIG. 7, the third photoresist layer 196 may be removed, and a fourth photoresist layer 198 may be formed on the insulating layer 160. The insulating layer 160 may be patterned by using the fourth photoresist layer 198 as a mask to form a second contact hole 168 exposing the low concentration emitter region 126.

Subsequently, an impurity of the second conductivity type may be ion implanted. The ion implantation energy and the impurity concentration in this process may be higher than the ion implantation energy and the impurity concentration for the low concentration emitter region 126, respectively. For example, the ion implantation energy may be from about 20 keV to about 50 keV, and the impurity concentration may be equal to or higher than about 1×10¹⁵ atm/cm³. The impurity implanted in this process may be heavier than the impurity for the first ion implantation, and may include As and BF₂, for example.

According to an example embodiment, doping of liquid or gaseous ions or partial doping using laser beams may be used instead of the ion implantation.

Referring to FIG. 8, the fourth photoresist layer 198 may be removed, and a base electrode 144 and an emitter electrode 148 may be formed on the insulating layer 160. The base electrode 144 may contact the low concentration base region 122 through the first contact hole 164 (shown in FIG. 6) of the insulating layer 160, and the emitter electrode 148 may be in contact with the low concentration emitter region 126 through the second contact hole 168 (shown in FIG. 6) of the insulating layer 160.

Finally, the photovoltaic layer 110 may be subjected to a second heat treatment such that the impurities introduced as shown in FIG. 6 and FIG. 7 may be activated to form a high concentration base region 124 and a high concentration emitter region 128. The second heat treatment may be performed for a duration shorter than a duration of the first heat treatment and under a temperature lower that the temperature of the first heat treatment. For example, the second heat treatment may be rapid thermal annealing at a temperature of about 820° C. for about 10 seconds. The second heat treatment may be performed under a nitrogen circumstance.

As a result of the second heat treatment, a material of the electrodes 144 and 148 and a material of the photovoltaic layer 110 may be combined to form first and second barrier layers 134 and 138 between the high concentration impurity regions 124 and 128 and the electrodes 144 and 148. The first and second barrier layers 134 and 138 may include a metal silicide, for example.

The temperature and the duration of the second heat treatment may be determined so that the pre-amorphized portions of the photovoltaic layer 110 formed in the processes shown in FIG. 6 and FIG. 7 may not be crystallized, and the first and second barrier layers 134 and 138 may be formed at the surfaces of the electrodes 144 and 148, thereby facilitating the movement of majority carriers and suppressing the movement of minority carriers.

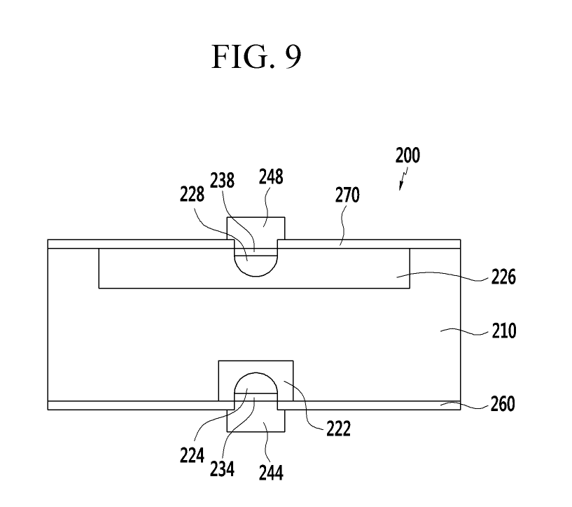

A solar cell according to an example embodiment is described in detail with reference to FIG. 9. FIG. 9 is a schematic sectional view of a solar cell according to an example embodiment.

Referring to FIG. 9, a solar cell 200 according to an example embodiment may include a photovoltaic layer 210, a base electrode 244, an emitter electrode 248, a first insulating layer 260, and a second insulating layer 270. The base electrode 244 and the first insulating layer 260 may be disposed under the photovoltaic layer 210, and the emitter electrode 248 and the second insulating layer 270 may be disposed on the photovoltaic layer 210. The photovoltaic layer 210 may include low concentration impurity regions including a low concentration base region 222 and a low concentration emitter region 226, and may further include high concentration impurity regions including a high concentration base region 224 and a high concentration emitter region 228. First and second barrier layers 234 and 238 may be disposed between the high concentration base region 224 and the base electrode 244 and between the high concentration emitter region 228 and the emitter electrode 248.

Unlike the structure shown in FIG. 1, the low concentration base region 222, the high concentration base region 224, and the base electrode 244 are disposed under the photovoltaic layer 210. The omission of a BSF layer is another difference between the solar cells 200 and 100 shown in FIG. 9 and FIG. 1.

The electrode structure shown in FIG. 2 may be applied to the solar cell 200.

The structures of other portions of the solar cell 200 may be similar to those shown in FIG. 1, and thus detailed description thereof is omitted.

Various properties of a solar cell according to experimental examples are measured and illustrated in Table 1.

TABLE 1

| | Example 1 | Example 2 | Example 3 | Example 4 | Example 5 |
|---|---|---|---|---|---|
| Voc (V) | 612 | 658 | 620 | 666 | 668 |
| Jsc (mA) | 36.03 | 41.32 | 36.70 | 42.76 | 43.67 |
| FF | 72.73 | 77.35 | 75.37 | 72.99 | 76.97 |
| PCE (%) | 16.04 | 20.47 | 17.15 | 20.78 | 22.45 |

In Table 1, Voc denotes open circuit voltage, Jsc denotes short-circuit current, FF denotes fill factor, and PCE denotes power conversion efficiency.

Each of Examples 1-5 has a structure shown in FIG. 1 with or without some exceptions. Example 1 has no barrier layer, Examples 2 and 3 have no low concentration impurity region, and Example 4 has no high concentration impurity region. In addition, Example 3 is formed at a high temperature instead of a low temperature. Example 5 has all of the low concentration impurity regions, high concentration impurity regions, and barrier layers.

Referring to Table 1, the open circuit voltage is increased when the low concentration impurity regions and the high concentration impurity regions are adapted, and the fill factor and the short-circuit current is increased when pre-amorphization and silicide barrier layers are adapted. Example 5 exhibits the most desirable properties compared with the other examples.

While some example embodiments have been particularly shown and described, it will be understood by one of ordinary skill in the art that variations in form and detail may be made therein without departing from the spirit and scope of the claims.

What is claimed is:

1. A solar cell comprising:
a photovoltaic layer including a crystalline photovoltaic material;
a first impurity region in the photovoltaic layer, the first impurity region being a first conductivity type;
a second impurity region in the photovoltaic layer, the second impurity region spaced apart from the first impurity region and being a second conductivity type;
a third impurity region in the first impurity region, the third impurity region having the first conductivity type and an impurity concentration higher than the first impurity region;
a fourth impurity region in the second impurity region, the fourth impurity region having the second conductivity type and an impurity concentration higher than the second impurity region;
a first barrier layer contacting the third impurity region;
a second barrier layer contacting the fourth impurity region;
a first electrode contacting the first barrier layer; and
a second electrode contacting the second barrier layer.

2. The solar cell of claim 1, wherein
an impurity included in the third impurity region is heavier than an impurity included in the first impurity region,
an impurity included in the fourth impurity region is heavier than an impurity included in the second impurity region,
the third impurity region is shallower than the first impurity region, and
the fourth impurity region is shallower than the second impurity region.

3. The solar cell of claim 1, wherein each of the first barrier layer and the second barrier layer comprises a metal silicide.

4. The solar cell of claim 1, wherein the first impurity region, the second impurity region, the third impurity region and the fourth impurity region abut onto a first surface of the photovoltaic layer.

5. The solar cell of claim 4, further comprising:
a back surface field layer on a second surface of the photovoltaic layer, the second surface opposite the first surface.

6. The solar cell of claim 1, wherein the first impurity region and the second impurity region abut onto opposite surfaces of the photovoltaic layer.

7. The solar cell of claim 1, wherein at least one of the first electrode and the second electrode has an inclined lateral surface.

8. A method of manufacturing a solar cell, the method comprising:
forming a first impurity region in a photovoltaic layer, the first impurity region including a first impurity of a first conductivity type and the photovoltaic layer including a crystalline photovoltaic material;
forming a second impurity region in the photovoltaic layer, the second impurity region including a second impurity of a second conductivity type and spaced apart from the first impurity region;
introducing a third impurity having the first conductivity type in the first impurity region, the third impurity having an impurity concentration higher than an impurity concentration of the first impurity region;
introducing a fourth impurity having the second conductivity type in the second impurity region, the fourth impurity having an impurity concentration higher than an impurity concentration of the second impurity region;
forming a first electrode on a first portion of the photovoltaic layer, the first portion including the third impurity;
forming a second electrode on a second portion of the photovoltaic layer, the second portion including the fourth impurity; and
heat treating the photovoltaic layer to activate the third impurity and the fourth impurity to form a third impurity region and a fourth impurity region.

9. The method of claim 8, wherein the forming a first impurity region and the forming a second impurity region comprise:
introducing the first impurity in the photovoltaic layer at a depth greater than a depth of the third impurity introduced in the first impurity region, the first impurity being lighter than the third impurity;
introducing the second impurity in the photovoltaic layer at a depth greater than a depth of the fourth impurity introduced in the second impurity region, the second impurity being lighter than the fourth impurity; and
heat treating the photovoltaic layer to activate the first impurity and the second impurity.

10. The method of claim 9, wherein the heat treating the photovoltaic layer to activate the third impurity and the fourth impurity is performed at a temperature lower than a temperature of the heat treating the photovoltaic layer to activate the first impurity and the second impurity and for a duration shorter than a duration of the heat treating the photovoltaic layer to activate the first impurity and the second impurity.

11. The method of claim 8, wherein the heat treating the photovoltaic layer to activate the third impurity and the fourth impurity comprises:
forming metal silicide layers between the first electrode and the third impurity region and between the second electrode and the fourth impurity region.
